(19) United States
(12) Patent Application Publication
(10) Pub. No.: US 2005/0207132 A1
(43) Pub. Date: Sep. 22, 2005

(54) Printed circuit board with electromagnetic interference (EMI) radiation suppressed

(75) Inventors: In-gu Kwak, Suwon-si (KR); Chi-hun Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/011,553

(22) Filed: Dec. 15, 2004

(30) Foreign Application Priority Data
Jan. 28, 2004 (KR) 2004-5437

(51) Int. Cl. H05K 7/06

(52) U.S. Cl. 361/760; 361/782; 361/783; 333/247; 333/12

(57) ABSTRACT

A printed circuit board with EMI radiation suppression is disclosed. An integrated circuit and an RC filter are disposed and wired in the printed circuit board including a top layer and a bottom layer. The integrated circuit has a first ground pin and a clock pin for outputting a clock signal, and the RC filter eliminates high frequency components of the clock signal. A second ground pin as one end of a capacitor of the RC filter is disposed to face the first ground pin of the integrated circuit, and no wiring is formed in a current return path directly connecting the second ground pin to the first ground pin. According to the present invention, the RC filter is disposed and wired in consideration of the EMI radiation characteristics, so the EMI radiation can be suppressed.

### CROSS-REFERENCE TO RELATED APPLICATIONS

This application claims the benefit under 35 U.S.C. §119(a) from Korean Patent Application No. 2004-5437, filed on Jan. 28, 2004, the entire contents of which is incorporated herein by reference.

### BACKGROUND OF THE INVENTION

1. Field of the Invention

The present invention relates to a printed circuit board for suppressing electromagnetic interference (EMI) radiation. More particularly, the present invention relates to a printed circuit board capable of suppressing the EMI radiation by disposing and wiring an RC filter in consideration of EMI radiation characteristics.

2. Description of the Related Art

EMI refers to interference caused by electromagnetic wave radiation produced in electronic circuits, and, since electromagnetic wave radiation higher than 30 MHz affects hens and the operation of other nearby electronic components, international standards limit the amount of the radiation that may be emitted by electronic circuits. There are various sources of EMI radiation, but a major source is a clock signal for integrated circuits (ICs). That is, the amount of the electromagnetic wave radiation causing the EMI increases as the clock signal frequency goes higher. Therefore, a printed circuit board (PCB) has at least one RC filter with resistors connected in series and capacitors connected in parallel.

FIG. 1 is a view for showing a conventional printed circuit board having an RC filter. Referring to FIG. 1, an IC 100 and an RC filter 110 are disposed and wired on a certain PCB layer. A clock signal is output from an output pin 100a of the IC 100, and input into the RC filter 110. The RC filter 110 includes a resistor 120 and a capacitor 130, and eliminates high frequency components of the clock signal.

Further, if a ground fill is used that is formed of gold film conductor between the IC 100 and the RC filter 110, a current return path is formed, as shown in the on dot dashed line, along which current return to a ground pin 100b of the IC 100. That is, the current passed through the capacitor 130 and the ground 130a of the capacitor 130 does not return directly to the ground pin 100b due to wirings 140 and 145, but over a different path to the ground pin 100b instead of the wirings 140 and 145. The different current return path lengthens the current return path so that the clock signal induces other signals and the EMI radiation increases as the current loop area becomes larger.

FIG. 2 is a view showing another conventional printed circuit board having a via and an RC filter. Referring to FIG. 2, the IC 200 is disposed on a top layer of the printed circuit board, and the RC filter 210 is disposed on a bottom layer of the printed circuit board. Reference numbers 240 and 245 denote wirings, and the top and bottom layers axe electrically connected by the via 250. Of the clock signal current output from the output pin 200a, the current passing through the capacitor 230 and the ground 230a returns to the ground pin 200b of the IC 200 through the via 250. Therefore, the current return path becomes shortened. However, the current return is disturbed as compared to when the current return does not pass through the via since the via 250 is a metal bar, which has a large inductance and impedance that increases the EMI radiation emissions since the current loop area also increases.

As described above, the conventional printed circuit board typically has an RC filter 120 or 220 disposed and wired thereon without consideration of EMI radiation, which causes, accordingly, the problem of increasing the amount of EMI radiation as the current return path and current loop area become longer and larger, respectively, and of disturbing the return of the current in an original state as the current returns through the via 250.

### SUMMARY OF THE INVENTION

The present invention has been developed in order to solve the above drawbacks and other problems associated with the conventional arrangement. An aspect of the present invention is to provide a printed circuit board capable of suppressing EMI radiation by disposing and wiring an RC filter thereon in consideration of EMI radiation characteristics.

The forgoing and other objects and advantages are substantially realized by providing a printed circuit board having two or more layers including a top layer and a bottom layer, comprising an integrated circuit having a first ground pin and a clock pin for outputting a clock signal; and an RC filter for eliminating the high frequency components of the clock signal, wherein a second ground pin is located such that one end of the capacitor of the RC filter is disposed to face the first ground pin of the integrated circuit, and no wiring is formed on a ground fill in a current return path directly connecting the second ground pin to the first ground pin. Preferably, the capacitor is disposed and wired on the same layer as the IC.

On the other hand, another aspect of the present invention is to provide a component-mounting method in a printed circuit board having two or more layers including a top layer and a bottom layer, comprising the steps of mounting an integrated circuit having a first ground pin and a clock pin for outputting a clock signal; and mounting an RC filter having at least one resistor for reducing the amplification of the clock signal and at least one capacitor for eliminating the high frequency components of the clock signal, wherein a second ground pin is located such that one end of the capacitor of the RC filter is disposed to face the first ground pin of the integrated circuit, and no wiring is formed on a ground fill in a current return path directly connecting the second ground pin to the first ground pin.

### BRIEF DESCRIPTION OF THE DRAWINGS

The above aspects and features of the present invention will be more apparent by describing certain embodiments of the present invention with reference to the accompanying drawings, in which:

FIG. 1 is a view showing a conventional printed circuit board having an RC filter thereon;

FIG. 2 is a view showing another conventional printed circuit board having a via and an RC filter thereon;

FIG. 3A is a perspective view for schematically showing a printed circuit board according to an embodiment of the present invention;

FIG. 3B is a plan view for schematically showing the printed circuit board of FIG. 3A;

FIG. 4 is a view for schematically showing a printed circuit board according to another embodiment of the present invention;

FIG. 5 is a view for schematically showing a printed circuit board according to yet another embodiment of the present invention; and

FIG. 6 is a view for schematically showing a printed circuit board according to still another embodiment of the present invention.

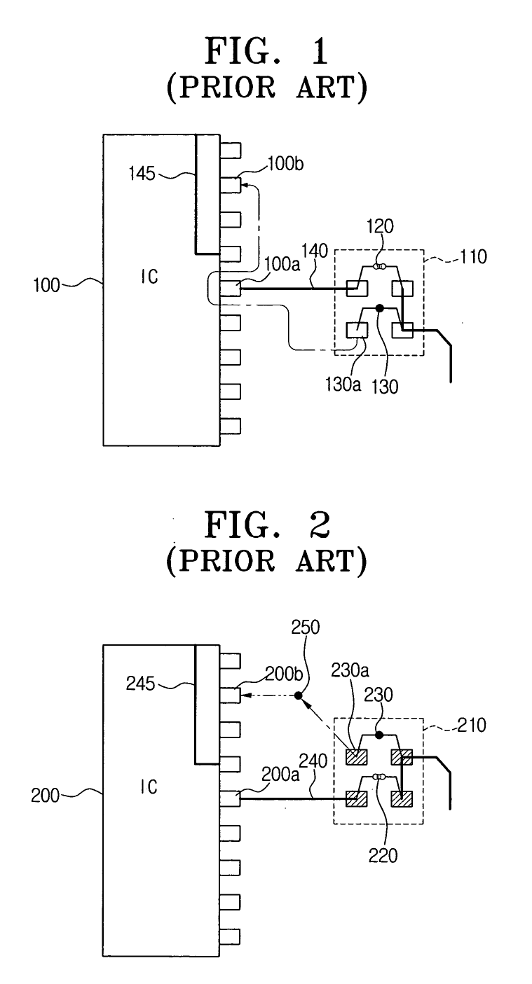

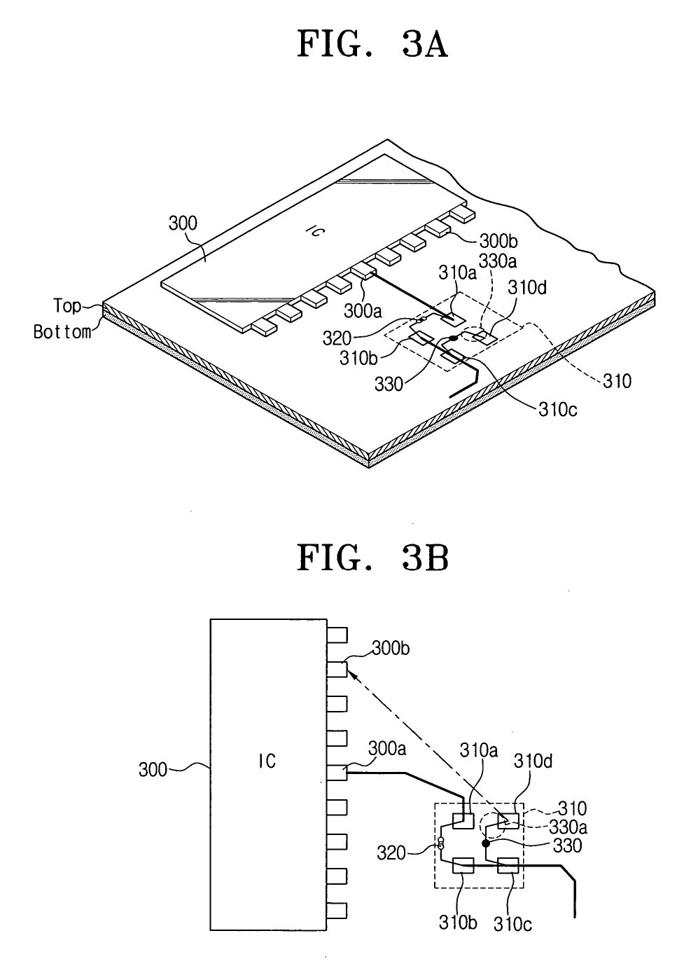

### DETAILED DESCRIPTION OF THE EXEMPLARY EMBODIMENTS

Hereafter, the present invention will be described in detail with reference to the accompanying drawings.

FIG. 3A is a view schematically showing a printed circuit board according to an embodiment of the present invention, and FIG. 3B is a plan view schematically showing the printed circuit board of FIG. 3A.

Referring to FIG. 3A and FIG. 3B, a printed circuit board consists of at least two layers that is, a top layer and a bottom layer. The printed circuit board has an IC 300 and a filter 310 mounted thereon, the IC 300 and the filter 310 are traced as shown in solid lines.

The IC 300 has a clock pin 300a for outputting a clock signal and a first ground pin 300b thereon, and the IC 300 is mounted on the top layer or on the bottom layer of the printed circuit board. The clock pin 300a outputs a clock signal, and the first ground pin 300b inputs current returning from the filter 310.

The RC filter 310 consists of at least one resistor and at least one capacitor, and embodiments of the present invention will be described together with such a filter having a resistor and a capacitor that is used to eliminate the high frequency components of the clock signal.

Both ends of the resistor 320 and capacitor 330 that form the filter 310 are electrically connected to the first through fourth pads 310a, 310b, 310c, and 310d, respectively.

The resistor 320 of the RC filter 310 reduces the magnitude of the clock signal output from the clock pin 300a. Further, the capacitor 330 of the RC filter 310 eliminates a high frequency signal, that is, noise, contained in the clock signal.

In embodiments of the present invention, the IC 300 and RC filter 310 are disposed and wired to meet the conditions as below. First, the second ground pin 330a forming one end of the capacitor 330 is mounted to the fourth pad 310d, and disposed to face the first ground pin 300b of the IC 300.

Further, the capacitor 330 of the filter RC 310 is disposed on the same layer as the IC 300 outputting the clock signal. In FIG. 3a, the IC 300, resistor 320, and capacitor 330 are disposed and wired on the top layer of the printed circuit board. In here, no wiring is formed on the ground fill in a direct current return path from the second ground pin 330a to the first ground pin 300b.

Thus, the return path is formed, as shown by the one-dot dashed line, for current returning to the first ground pin 300b through the second ground pin 330a of the RC filer 310. That is, the length of the return path (shown by the one-dot dashed line) for current entering the first ground pin 300b through the second ground pin 330a of the capacitor 330 is minimized.

Thus, the length of the current return path is minimized, so the current loop area is also minimized. Further, the IC 300 and the second ground pin 330a are disposed on the same layer, so current returns to the first ground pin 300b through the ground surface or the ground fill having less impedance rather than through a via (not shown). That is, the EMI radiation is reduced as expressed in Equation 1, with the above condition satisfied.

$${E}_{ϕ} = {Z}_{0} \cdot \frac{π}{{C}_{0}^{2}} \cdot \frac{1}{R} \cdot {f}^{2} \cdot A \cdot I \qquad [ Equation 1 ]$$

where E₁₀₀ denotes EMI radiation, Z₀ impedance, C₀ capacitance, R resistance, f a frequency, A a current loop area, and I a current. Equation 1 shows that the minimization of a current return path minimizes the area A, which reduces the noise of a digital signal, and thereby reduces the E₁₀₀.

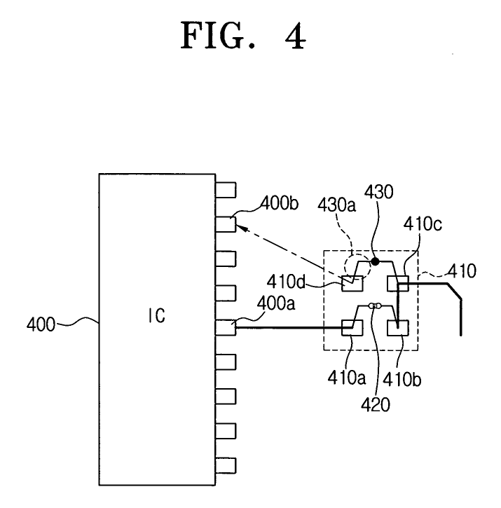

FIG. 4 is a view for schematically showing a printed circuit board according to another embodiment of the present invention.

A detailed description will be omitted of IC 400, clock pin 400a, first ground pin 400b, RC filter 410, first to fourth pads 410a, 410b, 410c, and 410d, resistor 420, capacitor 430, and second ground pin 430a as shown in FIG. 4, since those specific components in FIG. 4 are disposed and wired in a similar way that the IC 300, clock pin 300a, first ground pin 300b, RC filter 310, first to fourth pads 310a, 310b, 310c, and 310d, respectively, resistor 320, capacitor 330, and second ground pin 330a as shown in FIG. 3 are disposed and wired.

In FIG. 4, the second ground pin 430a forming one end of the capacitor 430 is wired to the fourth pad 410d, and disposed to face the first ground pin 400b of the IC 400. Further, the capacitor 430 is disposed on the same layer as the IC 400 outputting the clock signal. In FIG. 4, no wiring is formed on the ground fill in the current return path (shown by the one-dot dashed line) from the second ground pin 430a to the first ground pin 400b. However, the resistor 420 and capacitor 430 can be disposed lengthwise to be not parallel with the length of the IC 400, in a different way from FIG. 3a and FIG. 3b.

FIG. 5 is a view for schematically showing a printed circuit board according to yet another preferred embodiment of the present invention. A detailed description win be omitted of IC 500, clock pin 500a, first ground pin 500b, RC filter 510, first to fourth pads 510a, 510b, 510c, 510d, resistor 520, capacitor 530, and second ground pin 530a as shown in FIG. 5, since those specific components in FIG. 5 are disposed and wired in a similar manner as IC 300, clock pin 300a, first ground pin 300b, RC filter 310, first to fourth pads 310a, 310b, 310c, and 310d, respectively, resistor 320, capacitor 330, and second ground pin 330a as shown in FIG. 3 are disposed and wired. However, the first and second pads 510a and 510b shown in oblique lines in FIG. 5 are disposed on a different layer from the IC 300.

In FIG. 5, the second ground pin 530a forming one end of the capacitor 530 is wired to the fourth pad 510d, and disposed to face the first ground pin 500b of the IC 500. The resistor 520 is disposed on a different layer from the IC 500, but the capacitor 530 is disposed on the same layer as the IC 500. In this embodiment, no wiring is formed in the current return path (shown by the one-dot chain line) from the second ground pin 530a to the first ground pin 500b. Further, the resistor 520 and the capacitor 530 are disposed to be parallel to the IC 500 in the length direction.

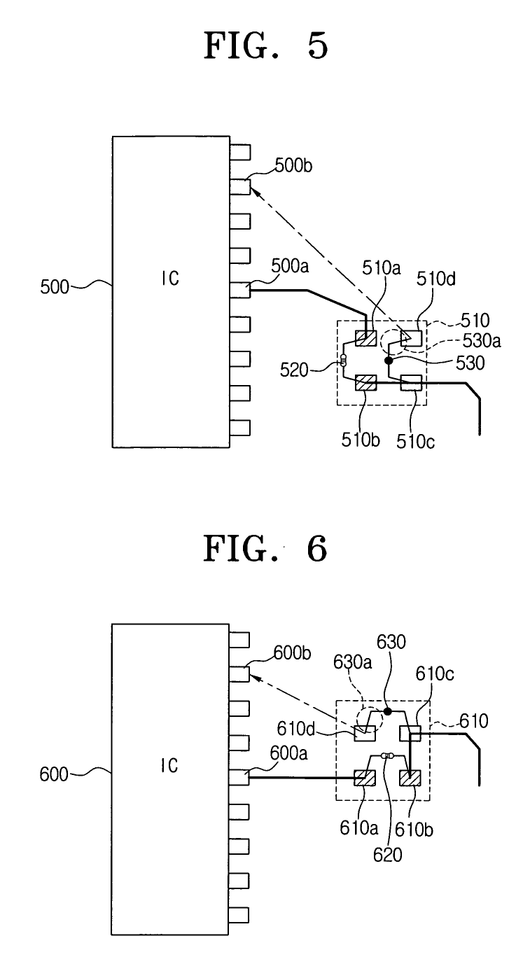

FIG. 6 is a view for schematically showing a printed circuit board according to still another embodiment of the present invention. A detailed description will be omitted of IC 600, clock pin 600a, first ground pin 600b, first to fourth pads 610a, 610b, 610c, and 610d, resistor 520, capacitor 630, and second ground pin 630a as shown in FIG. 6, since those specific components in FIG. 6 are disposed and wired in a similar manner as IC 300, clock pin 300a, first ground pin 300b, RC filter 310, first to fourth pads 310a, 310b, 310c, and 310d, respectively, resistor 320, capacitor 330, and second ground pin 330a as shown in FIG. 3 are disposed and wire.

However, the first and second pads 610a and 610b shown in oblique lines in FIG. 6 are disposed in a different layer than the IC 300.

In FIG. 6, the second ground pin 630a forms one end of the capacitor 630 is disposed and wired to face the first ground pin 600b of the IC 600, when wired to the fourth pad 610d. The resistor 620 is disposed on a different layer than the IC 600, but the capacitor 630 is disposed on the same layer as the IC 600. In this embodiment, no wiring is formed in the current return path (shown by the one-dot dashed line) from the second ground pin 630a to the first ground pin 600b. Further, the resistor 620 and capacitor 630 are disposed to be perpendicular with the length of the IC 600.

In the embodiments shown in FIG. 4 to FIG. 6, the circuit return path (shown by the one-dot dashed line) is minimized along the return path to the first ground pins 300b, 400b, 500b, and 600b from the RC filters 310, 410, 510, and 610, respectively. Thus, the current loop area and noise due to the clock signal (that is, a digital signal) are reduced as described above, so the EMI radiation is suppressed as expressed in Equation 1.

As aforementioned so far, the printed circuit board with the EMI radiation suppressed according to the embodiments of the present invention minimizes the return path of current returning from the filter to the IC by disposing and wiring the ground pin of the capacitor to face the ground pin of the IC as well as the IC and the capacitor of the filter to be on the same layer. Thus, the current loop area is minimized, and a high frequency signal contained in the clock signal is efficiently eliminated so the EMI radiation can also be suppressed.

The foregoing embodiment and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

1. A printed circuit board having two or more layers including a top layer and a bottom layer, comprising
an integrated circuit having a first ground pin and a clock pin for outputting a clock signal; and
an RC filter comprising at least one resistor and at least one capacitor for eliminating high frequency components from the clock signal, wherein a second ground pin of one end of the at least one capacitor of the RC filter is disposed to face the first ground pin of the integrated circuit, and no wiring is formed in a current return path directly connecting the second ground pin to the first ground pin.

2. The printed circuit board as claimed in claim 1, wherein the capacitor is disposed and wired on the same layer as the integrated circuit.

3. The printed circuit board as claimed in claim 1, wherein the resistor and capacitor of the RC filter are disposed to be perpendicular to the length of the integrated circuit.

4. The printed circuit board as claimed in claim 1, wherein the resistor and capacitor of the RC filter are disposed to be parallel to the length of the integrated circuit.

5. The printed circuit board as claimed in claim 1, wherein the second ground pin is placed is disposed on the printed circuit board to minimize the current return path from the second ground pin to the first ground pin.

6. A method for mounting components in a printed circuit board having two or more layers including a top layer and a bottom layer, comprising the steps of:
mounting an integrated circuit having a first ground pin and a clock pin for outputting a clock signal; and
mounting an RC filter having at least one resistor for reducing the amplification of the clock signal and at least one capacitor for eliminating the high frequency components of the clock signal, wherein a second ground pin is located such that one end of the capacitor of the RC filter is disposed to face the fix ground pin of the integrated circuit, and no wiring is formed on a ground fill in a current return path directly connecting the second ground pin to the first ground pin.

7. The printed circuit board as claimed in claim 6, wherein the capacitor is disposed and wired on the same layer as the integrated circuit.

8. The method as claimed in claim 6, wherein the resistor and capacitor of the RC filter are disposed to be perpendicular to the length of the integrated circuit.

9. The method as claimed in claim 6, wherein the resistor and capacitor of the RC filter are disposed to be parallel to the length of the integrated circuit.

10. The method as claimed in claim 6, wherein the second ground pin is placed is disposed on the printed circuit board to minimize the current return path from the second ground pin to the first ground pin.
